(19) United States
(12) Patent Application Publication
(10) Pub. No.: US 2021/0185817 A1
(43) Pub. Date: Jun. 17, 2021

(54) CIRCUIT DEVICE AND POWER CONVERSION APPARATUS

(71) Applicant: Mitsubishi Electric Corporation, Chiyoda-ku, Tokyo (JP)

(72) Inventors: Kenta FUJII, Chiyoda-ku, Tokyo (JP); Takashi KUMAGAI, Chiyoda-ku, Tokyo (JP); Tomohito FUKUDA, Chiyoda-ku, Tokyo (JP); Takashi HIRATSUKA, Chiyoda-ku, Tokyo (JP); Koichi AOKI, Chiyoda-ku, Tokyo (JP)

(73) Assignee: Mitsubishi Electric Corporation, Chiyoda-ku, Tokyo (JP)

(21) Appl. No.: 17/257,059

(22) PCT Filed: Jul. 11, 2019
(86) PCT No.: PCT/JP2019/027514

§ 371 Date: Dec. 30, 2020

(30) Foreign Application Priority Data
Aug. 20, 2018 (JP) 2018-153995

(51) Int. Cl. H05K 1/16; H05K 7/20; H05K 1/02; H01F 27/02; H02M 3/28

(52) U.S. Cl. CPC H05K 1/16; H05K 7/20; H02M 3/28; H01F 27/02; H05K 1/02

(57) ABSTRACT

A circuit device includes a core, a first circuit board, a second circuit board, a heat dissipation member, a first heat transfer member, and a second heat transfer member. The first circuit board includes a first coil pattern surrounding at least a part of the core. The second circuit board includes a second coil pattern surrounding at least a part of the core. The first heat transfer member is in surface contact with the first circuit board and the heat dissipation member. The second heat transfer member is in surface contact with the first circuit board and the second circuit board.

### TECHNICAL FIELD

The present invention relates to a circuit device and a power conversion apparatus.

### BACKGROUND ART

Japanese Patent Laying-Open No. 2017-41998 (PTL 1) discloses a power conversion apparatus including a transformer. The transformer includes a core, a primary coil pattern, and a secondary coil pattern. A first substrate with the primary coil pattern and a second substrate with the secondary coil pattern are stacked on each other.

### CITATION LIST

### Patent Literature

PTL 1: Japanese Patent Laying-Open No. 2017-41998

### SUMMARY OF INVENTION

### Technical Problem

In the transformer and the power conversion apparatus disclosed in PTL 1, the first substrate with the primary coil pattern and the first substrate with the secondary coil pattern are stacked on each other while being spaced away from each other. As a current is flowed through the primary coil pattern and the secondary coil pattern to operate the transformer and the power conversion apparatus, thus, it is difficult to dissipate heat generated in the primary coil pattern and the secondary coil pattern to outside of the transformer and the power conversion apparatus. The temperature of the transformer and the temperature of the power conversion apparatus rise, leading to an increased power loss in the transformer and the power conversion apparatus. The present invention has been made in view of the above problem. An object of the present invention is to provide a circuit device and a power conversion apparatus that can prevent or reduce a temperature rise and a power loss during operation.

### Solution to Problem

A circuit device of the present invention includes a core, a first circuit board, a second circuit board, a heat dissipation member, a first heat transfer member, and a second heat transfer member. The first circuit board includes a first substrate and a first coil pattern. The first coil pattern surrounds at least a part of the core. The second circuit board includes a second substrate and a second coil pattern. The second coil pattern surrounds at least a part of the core. The heat dissipation member supports the core, the first circuit board, and the second circuit board. The first heat transfer member is disposed between the first circuit board and the heat dissipation member and is in surface contact with the first circuit board and the heat dissipation member. The second heat transfer member is disposed between the first circuit board and the second circuit board and is in surface contact with the first circuit board and the second circuit board.

A power conversion apparatus of the present invention includes a circuit device of the present invention and an inverter circuit that controls a current flowing through the first coil pattern.

### Advantageous Effects of Invention

As a current is flowed through the first coil pattern and the second coil pattern to operate the circuit device and the power conversion apparatus, the first coil pattern and the second coil pattern generate heat. Heat generated in the first coil pattern is transferred through the first heat transfer member to the heat dissipation member with a relatively low thermal resistance. Heat generated in the second coil pattern is transferred through the second heat transfer member, the first circuit board, and the first heat transfer member to the heat dissipation member with a relatively low thermal resistance. A temperature rise and a power loss during operation of the circuit device and the power conversion apparatus can thus be prevented or reduced in the circuit device and the power conversion apparatus.

### BRIEF DESCRIPTION OF DRAWINGS

FIG. 1 is a circuit diagram of a power conversion apparatus according to Embodiment 1.

FIG. 2 is a schematic perspective view of a circuit device according to Embodiment 1.

FIG. 3 is an exploded schematic perspective view of the circuit device according to Embodiment 1.

FIG. 4 is a schematic plan view of the circuit device according to Embodiment 1.

FIG. 5 is a schematic sectional view of the circuit device according to Embodiment 1, which is taken along the sectional line V-V shown in FIG. 4.

FIG. 6 is a schematic plan view of a circuit device according to Embodiment 2.

FIG. 7 is a schematic sectional view of the circuit device according to Embodiment 2, which is taken along the sectional line VII-VII shown in FIG. 6.

FIG. 8 is a schematic plan view of a first circuit board (with a first electronic component omitted) included in a circuit device according to Embodiment 3.

FIG. 9 is a schematic bottom view of the first circuit board included in the circuit device according to Embodiment 3.

FIG. 10 is a schematic plan view of a second circuit board (with a second electronic component omitted) included in the circuit device according to Embodiment 3.

FIG. 11 is a schematic bottom view of the second circuit board included in the circuit device according to Embodiment 3.

FIG. 12 is a schematic sectional view of a circuit device according to Embodiment 4.

FIG. 13 is a schematic plan view of a first circuit board included in the circuit device according to Embodiment 4.

FIG. 14 is a schematic plan view of a second circuit board included in the circuit device according to Embodiment 4.

FIG. 15 is a schematic sectional view of a circuit device according to Embodiment 5.

FIG. 16 is a schematic sectional view of a circuit device according to Embodiment 6.

FIG. 17 is a schematic plan view of a first circuit board included in the circuit device according to Embodiment 6.

FIG. 18 is a schematic plan view of a second circuit board included in the circuit device according to Embodiment 6.

FIG. 19 is a schematic sectional view of a circuit device according to Embodiment 7.

FIG. 20 is a schematic plan view of a first circuit board included in the circuit device according to Embodiment 7.

FIG. 21 is a schematic plan view of a second circuit board included in the circuit device according to Embodiment 7.

FIG. 22 is a schematic sectional view of a circuit device according to Embodiment 8.

FIG. 23 is a schematic plan view of a circuit device according to Embodiment 9.

FIG. 24 is a schematic sectional view of the circuit device according to Embodiment 9, which is taken along the sectional line XXIV-XXIV shown in FIG. 23.

FIG. 25 is a schematic plan view of a circuit device according to Embodiment 10.

FIG. 26 is a schematic sectional view of the circuit device according to Embodiment 10, which is taken along the sectional line XXVI-XXVI shown in FIG. 25.

FIG. 27 is a schematic plan view of a first circuit board included in a circuit device according to Embodiment 11.

### DESCRIPTION OF EMBODIMENTS

Embodiments of the present invention will now be described. Like components are designated by like reference numerals, description of which will not be repeated.

### Embodiment 1

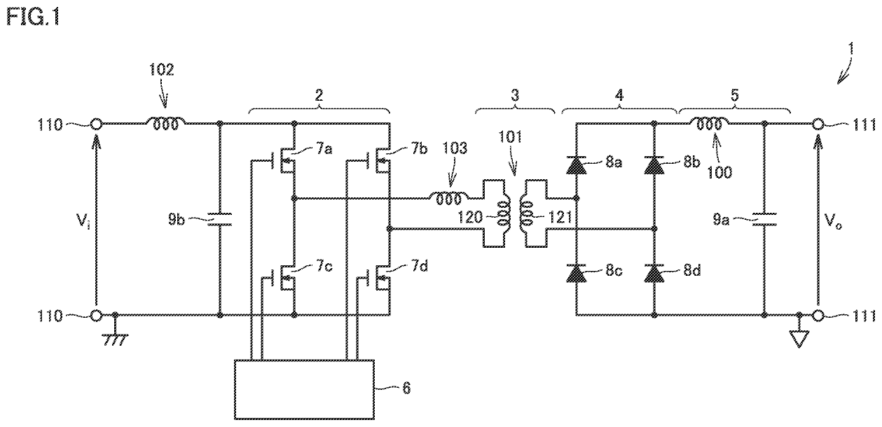

An example circuit configuration of a power conversion apparatus 1 of the present embodiment will be described with reference to FIG. 1. Power conversion apparatus 1 of the present embodiment is, for example, a DC-DC converter. Power conversion apparatus 1 includes an inverter circuit 2, a transformer circuit 3, a rectifier circuit 4, a smoothing circuit 5 including a coil device 100, and a control circuit 6. Power conversion apparatus 1 converts a direct-current (DC) voltage Vᵢ supplied to an input terminal 110 to a DC voltage Vₒ and outputs DC voltage Vₒ from an output terminal 111.

Inverter circuit 2 includes switching elements 7a, 7b, 7c, 7d. Each of switching elements 7a, 7b, 7c, 7d is, for example, a metal-oxide semiconductor field-effect transistor (MOSFET), an insulated gate bipolar transistor (IGBT), or the like. Each of switching elements 7a, 7b, 7c, 7d is formed of a semiconductor material such as silicon (Si), silicon carbide (SiC), or gallium nitride (GaN).

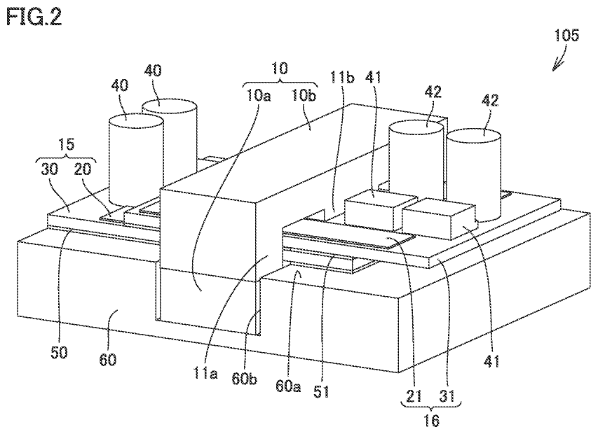

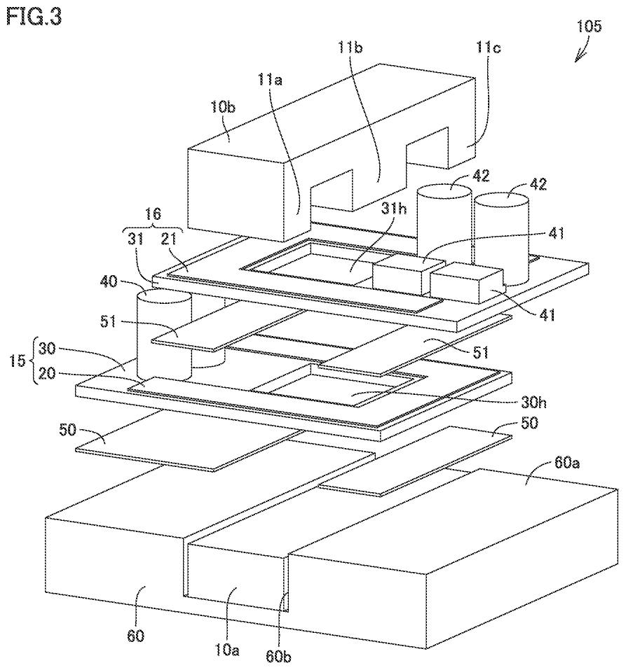

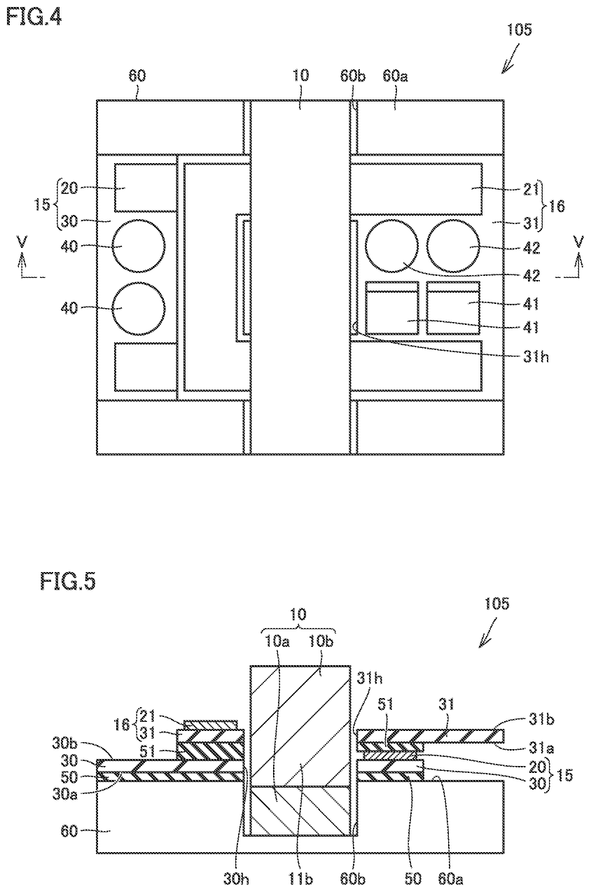

Transformer circuit 3 includes a transformer 101. Transformer 101 includes a primary-side coil conductor 120, a core 10 (see FIGS. 2 to 5), and a secondary-side coil conductor 121. For example, primary-side coil conductor 120 is a high-voltage-side coil conductor, and secondary-side coil conductor 121 is a low-voltage-side coil conductor. Primary-side coil conductor 120 is connected to inverter circuit 2. Secondary-side coil conductor 121 is connected to rectifier circuit 4. Secondary-side coil conductor 121 is magnetically coupled to primary-side coil conductor 120 with core 10 therebetween.

Rectifier circuit 4 includes diodes 8a, 8b, 8c, 8d. Each of diodes 8a, 8b, 8c, 8d is formed of a semiconductor material such as Si, SiC, or GaN. Smoothing circuit 5 includes coil device 100 serving as a smoothing coil and a capacitor 9a.

Power conversion apparatus 1 includes, at the stage preceding inverter circuit 2, a coil device 102 serving as a smoothing coil and a capacitor 9b. Power conversion apparatus 1 includes a coil device 103 serving as a resonance coil between inverter circuit 2 and transformer circuit 3.

Power conversion apparatus 1 receives, for example, a DC voltage Vᵢ of not less than 100 V and not greater than 600 V. Power conversion apparatus 1 outputs, for example, a DC voltage Vₒ of not less than 12 V and not greater than 16 V. Specifically, DC voltage Vᵢ supplied to input terminal 110 is converted to a first alternating-current (AC) voltage by inverter circuit 2. The first AC voltage is converted to a second AC voltage lower than the first AC voltage by transformer circuit 3. The second AC voltage is rectified by rectifier circuit 4. Smoothing circuit 5 smoothes a voltage output from rectifier circuit 4. Power conversion apparatus 1 outputs, from output terminal 111, DC voltage Vₒ output from smoothing circuit 5.

Input terminal 110, output terminal 111, and at least one of switching elements 7a, 7b, 7c, 7d, diodes 8a, 8b, 8c, 8d, and capacitors 9a, 9b are mounted on, for example, a circuit board (first circuit board 15, second circuit board 16 (see FIGS. 2 to 5)). The circuit board is attached to a heat dissipation member 60 (see FIGS. 2 to 5). Heat dissipation member 60 is, for example, a housing of power conversion apparatus 1. Any other electronic component may be mounted on the circuit board. Input terminal 110, output terminal 111, and an electronic component including at least one of switching elements 7a, 7b, 7c, 7d, diodes 8a, 8b, 8c, 8d, and capacitors 9a, 9b may be mounted in the housing of power conversion apparatus 1.

A circuit device 105 of the present embodiment will be described with reference to FIGS. 2 to 5. Power conversion apparatus 1 includes circuit device 105. Note that power conversion apparatus 1 may include any of circuit devices 105b to 105i of Embodiments 2 to 11 in place of circuit device 105 of Embodiment 1. Circuit device 105 is, for example, transformer 101 included in power conversion apparatus 1. Circuit device 105 may be any of coil devices 100, 102, 103. Circuit device 105 includes core 10, first circuit board 15, second circuit board 16, heat dissipation member 60, a first heat transfer member 50, and a second heat transfer member 51.

Core 10 includes a magnetic material. Core 10 is, for example, a ferrite core of manganese-zinc (Mn—Zn)-based ferrite or nickel-zinc (Ni—Zn)-based ferrite, an amorphous core, or an iron dust core. Core 10 includes, for example, a first core portion 10a and a second core portion 10b. For example, core 10 is an EI-type core with first core portion 10a having an I-shape and second core portion 10b having an E-shape. Second core portion 10b has a first leg 11a, a second leg 11b, and a third leg 11c. Second leg 11b is located between first leg 11a and third leg 11c. First core portion 10a is disposed in a recess 60b of heat dissipation member 60. Second core portion 10b is stacked on first core portion 10a. The shape of core 10 is not particularly limited, and core 10 may be an EE-type core, a U-type core, a UU-type core, an EER-type core, or an ER-type core.

First circuit board 15 includes a first substrate 30 and a first coil pattern 20. First circuit board 15 is, for example, a printed circuit board. First substrate 30 includes a first main surface 30a facing a surface 60a of heat dissipation member 60 and a second main surface 30b opposite to first main surface 30a. First substrate 30, which is formed of an electrically insulating material, is an insulated substrate. First substrate 30 is formed of, for example, glass-reinforced epoxy resin, phenolic resin, polyphenylene sulfide (PPS), polyetheretherketone (PEEK), or the like. First substrate 30 may be formed of a ceramic material such as aluminum oxide (Al₂O₃) or aluminum nitride (AlN). First substrate 30 may be provided with a first through hole 30h extending from first main surface 30a to second main surface 30b. Second leg 11b of core 10 is inserted into first through hole 30h. Second leg 11b of core 10 passes through first circuit board 15 (first substrate 30).

First coil pattern 20 corresponds to primary-side coil conductor 120 (see FIG. 1). First coil pattern 20 is provided on first main surface 30a, on second main surface 30b, or in first substrate 30. First circuit board 15 is a single-sided wiring board with first coil pattern 20 provided on first main surface 30a or on second main surface 30b. First coil pattern 20 is made of a material having a higher electrical resistivity and a lower thermal conductivity than those of first substrate 30. First coil pattern 20 is formed of a conductive material such as copper (Cu), silver (Ag), gold (Au), tin (Sn), copper (Cu) alloy, nickel (Ni) alloy, gold (Au) alloy, silver (Ag) alloy, or tin (Sn) alloy. First coil pattern 20 is, for example, a thin conductor layer having a thickness of not less than 1 μm and not greater than 5000 μm.

First coil pattern 20 surrounds at least a part of core 10. First coil pattern 20 surrounds, for example, at least one of first leg 11a, second leg 11b, and third leg 11c. Particularly, first coil pattern 20 surrounds second leg 11b of core 10 through a space between first leg 11a and second leg 11b and a space between second leg 11b and third leg 11c. First coil pattern 20 surrounding at least a part of core 10 means that first coil pattern 20 is wound a half of a turn around at least a part of core 10. Herein, a coil pattern having the number of turns, which is one, means that the coil pattern passes through all the spaces around second leg 11b, which are surrounded by first core portion 10a and second core portion 10b, in a single winding operation. A part of first coil pattern 20 may be located between first core portion 10a and second core portion 10b.

As shown in FIGS. 2 to 4, first electronic components 40 forming inverter circuit 2 (see FIG. 1) are mounted on at least one of first circuit board 15 and second circuit board 16. Particularly, first electronic components 40 may be mounted on second main surface 30b of first circuit board 15. First electronic components 40 are, for example, switching elements 7a, 7b, 7c, 7d (see FIG. 1). First electronic components 40 are electrically connected to first coil pattern 20.

Second circuit board 16 includes a second substrate 31 and a second coil pattern 21. Second circuit board 16 is, for example, a printed circuit board. Second substrate 31 includes a third main surface 31a facing first circuit board 15 and a fourth main surface 31b opposite to third main surface 31a. Second substrate 31, which is formed of an electrically insulating material, is an insulated substrate. Second substrate 31 is formed of, for example, glass-reinforced epoxy, phenolic resin, polyphenylene sulfide (PPS), polyetheretherketone (PEEK), or the like. Second substrate 31 may be formed of a ceramic material such as aluminum oxide (Al₂O₃) or aluminum nitride (AlN). Second substrate 31 may be provided with a second through hole 31h extending from third main surface 31a to fourth main surface 31b. Second leg 11b of core 10 is inserted into second through hole 31h. Second leg 11b of core 10 passes through second circuit board 16 (second substrate 31).

Second coil pattern 21 corresponds to secondary-side coil conductor 121 (see FIG. 1). Second coil pattern 21 is provided on third main surface 31a, on fourth main surface 31b, or in second substrate 31. Second circuit board 16 is a single-sided wiring board with second coil pattern 21 provided on third main surface 31a or on fourth main surface 31b. Second coil pattern 21 is provided on a substrate different from that of first coil pattern 20. Second coil pattern 21 can thus be designed easily and independently of first coil pattern 20 in terms of shape, thickness, the number of turns, and the like. Second coil pattern 21 is made of a material having a lower electrical resistivity and a higher thermal conductivity than those of second substrate 31. Second coil pattern 21 is formed of a conductive material such as copper (Cu), silver (Ag), gold (Au), tin (Sn), copper (Cu) alloy, nickel (Ni) alloy, gold (Au) alloy, silver (Ag) alloy, or tin (Sn) alloy.

Second coil pattern 21 is a thin conductor layer having a thickness of, for example, not less than 1 μm and not greater than 5000 μm. The thickness of second coil pattern 21 may be different from the thickness of first coil pattern 20. For example, when power conversion apparatus 1 is a step-down DC/DC converter, a first current flowing through first coil pattern 20 corresponding to primary-side coil conductor 120 is smaller than a second current flowing through second coil pattern 21 corresponding to secondary-side coil conductor 121. The thickness of first coil pattern 20 may thus be smaller than the thickness of second coil pattern 21.

Second coil pattern 21 surrounds at least a part of core 10. Second coil pattern 21 surrounds, for example, at least one of first leg 11a, second leg 11b, and third leg 11c. Particularly, second coil pattern 21 surrounds second leg 11b of core 10 through, for example, the space between first leg 11a and second leg 11b and the space between second leg 11b and third leg 11c. Second coil pattern 21 surrounding at least a part of core 10 means that second coil pattern 21 is wound a half or more of a turn around at least a part of core 10. A part of second coil pattern 21 may be located between first core portion 10a and second core portion 10b.

Regarding at least a part of core 10 (e.g., second leg 11b of core 10), second coil pattern 21 is wound in a direction different from that of first coil pattern 20. Second coil pattern 21 is magnetically coupled to first coil pattern 20 with core 10 therebetween. Second circuit board 16 covers at least a part of first circuit board 15 and mechanically protects first circuit board 15.

As shown in FIGS. 2 to 4, second electronic components 41, 42 forming rectifier circuit 4 (see FIG. 1) are mounted on at least one of first circuit board 15 and second circuit board 16. Particularly, second electronic components 41, 42 may be mounted on fourth main surface 31b of second circuit board 16. Second electronic components 41, 42 are, for example, diodes 8a, 8b, 8c, 8d (see FIG. 1). Second electronic components 41, 42 are electrically connected to second coil pattern 21.

Heat dissipation member 60 supports core 10, first circuit board 15, and second circuit board 16. Heat dissipation member 60 further supports first heat transfer member 50 and second heat transfer member 51. Heat dissipation member 60 has surface 60a facing first circuit board 15. Recess 60b is provided in surface 60a of heat dissipation member 60. A part (first core portion 10a) of core 10 is housed in recess 60b. Heat dissipation member 60 is in surface contact with core 10 (first core portion 10a). As a current is flowed through first coil pattern 20 and second coil pattern 21 to operate circuit device 105, an energy loss due to a magnetic loss occurs in core 10, thus causing core 10 to generate heat. The heat generated in core 10 can be transmitted to heat dissipation member 60 with a low thermal resistance. A temperature rise of core 10 and a power loss in core 10 during operation of circuit device 105 can be prevented or reduced.

Core 10, first circuit board 15, and second circuit board 16 may be fixed to heat dissipation member 60 with a fixing member 70 (see FIG. 25) such as a screw, a machine screw, or a rivet. Core 10, first circuit board 15, and second circuit board 16 may be pressed toward heat dissipation member 60 with a spring (not shown) to be fixed to heat dissipation member 60.

Heat dissipation member 60 is, for example, a part of the housing of power conversion apparatus 1 which houses core 10, first circuit board 15, and second circuit board 16. Circuit device 105 (transformer 101) can thus be mounted in power conversion apparatus 1 by merely fixing core 10, first circuit board 15, second circuit board 16, first heat transfer member 50, and second heat transfer member 51 to heat dissipation member 60. Since circuit device 105 does not need to be assembled before circuit device 105 is mounted in power conversion apparatus 1, the manufacturing cost of power conversion apparatus 1 can be reduced. Further, since a housing of circuit device 105 per se is not necessary, power conversion apparatus 1 including circuit device 105 can be miniaturized. Heat dissipation member 60 has a thermal conductivity of not less than 0.1 W/(m·K). Heat dissipation member 60 may have a thermal conductivity of not less than 1.0 W/(m·K) or may have a thermal conductivity of not less than 10.0 W/(m·K). Heat dissipation member 60 may be electrically grounded.

Heat dissipation member 60 is formed of, for example, a metallic material such as copper (Cu), aluminum (Al), iron (Fe), ferric (Fe) alloy (e.g., SUS304), copper (Cu) alloy (e.g., phosphor bronze), or aluminum (Al) alloy (e.g., ADC12). Heat dissipation member 60 may be formed of a resin material containing a thermally conductive filler. The resin material used in heat dissipation member 60 is, for example, polybutylene terephthalate (PBT), polyphenylene sulfide (PPS), polyetheretherketone (PEEK), or the like. Heat dissipation member 60 is formed of, for example, a nonmagnetic material. Heat dissipation member 60 is manufactured by a method such as cutting, die casting, forging, or molding using a die.

First heat transfer member 50 is disposed between first circuit board 15 and heat dissipation member 60 and is in surface contact with first circuit board 15 and heat dissipation member 60. First circuit board 15, first heat transfer member 50, and heat dissipation member 60 are stacked on each other. First heat transfer member 50 thermally connects first circuit board 15 to heat dissipation member 60 with a relatively low thermal resistance. First heat transfer member 50 is a first heat transfer sheet.

First heat transfer member 50 may have electrical insulating properties. First heat transfer member 50 having electrical insulating properties may be in surface contact with first coil pattern 20. First heat transfer member 50 may be in contact with core 10.

First heat transfer member 50 may be formed of a resin material such as silicone, urethane, epoxy, acrylonitrile butadiene styrene (ABS), polybutylene terephthalate (PBT), polyphenylene sulfide (PPS), phenol, or polyimide, a fibrous material such as glass fiber or aramid fiber, or a ceramic material such as aluminum oxide or aluminum nitride. First heat transfer member 50 may be a silicone rubber sheet or a urethane rubber sheet. First heat transfer member 50 may be formed of a silicone gel, a silicone grease, or a silicone adhesive.

First heat transfer member 50 has a thermal conductivity higher than that of each of first substrate 30 and second substrate 31. First heat transfer member 50 has a thermal conductivity of not less than 0.1 W/(m·K). First heat transfer member 50 may have a thermal conductivity of not less than 1.0 W/(m·K) or may have a thermal conductivity of not less than 10.0 W/(m·K). First heat transfer member 50 may have elasticity. First heat transfer member 50 may be crushed by pressing first circuit board 15 toward heat dissipation member 60.

Second heat transfer member 51 is disposed between first circuit board 15 and second circuit board 16 and is in surface contact with first circuit board 15 and second circuit board 16. First circuit board 15, second heat transfer member 51, and second circuit board 16 are stacked on each other. Second heat transfer member 51 is a second heat transfer sheet. Second heat transfer member 51 thermally connects second circuit board 16 to first circuit board 15 with a relatively low thermal resistance.

Second heat transfer member 51 may have electrical insulating properties. Second heat transfer member 51 having electrical insulating properties may be in surface contact with at least one of first coil pattern 20 and second coil pattern 21. Second heat transfer member 51 may be in contact with core 10.

Second heat transfer member 51 may be formed of a resin material such as silicone, urethane, epoxy, acrylonitrile butadiene styrene (ABS), polybutylene terephthalate (PBT), polyphenylene sulfide (PPS), phenol, or polyimide, a fibrous material such as glass fiber or aramid fiber, or a ceramic material such as aluminum oxide or aluminum nitride. Second heat transfer member 51 may be a silicone rubber sheet or a urethane rubber sheet. Second heat transfer member 51 may be formed of a silicone gel, a silicone grease, or a silicone adhesive. Second heat transfer member 51 may be formed of the same material as that of first heat transfer member 50 or may be formed of a material different from that of first heat transfer member 50.

Second heat transfer member 51 has a thermal conductivity higher than that of each of first substrate 30 and second substrate 31. Second heat transfer member 51 may have the same thermal conductivity as that of first heat transfer member 50 or may have a thermal conductivity different from that of first heat transfer member 50. Second heat transfer member 51 has a thermal conductivity of not less than 0.1 W/(m·K). Second heat transfer member 51 may have a thermal conductivity of not less than 1.0 W/(m·K) or may have a thermal conductivity of not less than 10.0 W/(m·K). Second heat transfer member 51 may have elasticity. Second heat transfer member 51 may be crushed by pressing second circuit board 16 toward first circuit board 15.

The effects of circuit device 105 and power conversion apparatus 1 of the present embodiment will be described.

Circuit device 105 of the present embodiment includes core 10, first circuit board 15, second circuit board 16, heat dissipation member 60, first heat transfer member 50, and second heat transfer member 51. First circuit board 15 includes first substrate 30 and first coil pattern 20. First coil pattern 20 surrounds at least a part of core 10. Second circuit board 16 includes second substrate 31 and second coil pattern 21. Second coil pattern 21 surrounds at least a part of core 10. Heat dissipation member 60 supports core 10, first circuit board 15, and second circuit board 16. First heat transfer member 50 is disposed between first circuit board 15 and heat dissipation member 60 and is in surface contact with first circuit board 15 and heat dissipation member 60. Second heat transfer member 51 is disposed between first circuit board 15 and second circuit board 16 and is in surface contact with first circuit board 15 and second circuit board 16.

As a current is flowed through first coil pattern 20 and second coil pattern 21 to operate circuit device 105, first coil pattern 20 and second coil pattern 21 generate heat. The heat generated in first coil pattern 20 is transferred through first heat transfer member 50 to heat dissipation member 60 with a relatively low thermal resistance. The heat generated in second coil pattern 21 is transferred through second heat transfer member 51, first circuit board 15, and first heat transfer member 50 to heat dissipation member 60 with a relatively low thermal resistance. A temperature rise and a power loss of circuit device 105 during operation of circuit device 105 can thus be prevented or reduced.

Heat generated in first electronic components 40 during operation of circuit device 105 is transferred through first circuit board 15 and first heat transfer member 50 to heat dissipation member 60 with a relatively low thermal resistance. Heat generated in second electronic components 41, 42 during operation of circuit device 105 is transferred through second circuit board 16, second heat transfer member 51, first circuit board 15, and first heat transfer member 50 to heat dissipation member 60 with a relatively low thermal resistance. A temperature rise and a power loss of circuit device 105 during operation of circuit device 105 can thus be prevented or reduced.

Power conversion apparatus 1 of the present embodiment includes circuit device 105 and an inverter circuit that controls a current flowing through first coil pattern 20. As a current is flowed through first coil pattern 20 and second coil pattern 21 to operate power conversion apparatus 1, first coil pattern 20 and second coil pattern 21 generate heat. The heat generated in first coil pattern 20 is transferred through first heat transfer member 50 to heat dissipation member 60 with a relatively low thermal resistance. The heat generated in second coil pattern 21 is transferred through second heat transfer member 51, first circuit board 15, and first heat transfer member 50 to heat dissipation member 60 with a relatively low thermal resistance. A temperature rise and a power loss of power conversion apparatus 1 during operation of power conversion apparatus 1 can thus be prevented or reduced.

### Embodiment 2

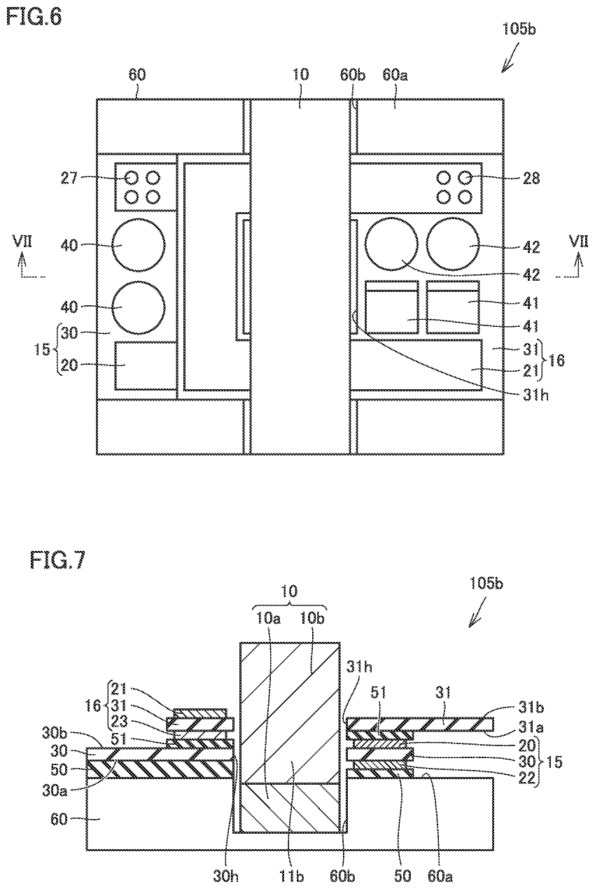

Circuit device 105b according to Embodiment 2 will be described with reference to FIGS. 6 and 7. Circuit device 105b of the present embodiment is similar in configuration to circuit device 105 of Embodiment 1 and is different mainly in the following respects.

In circuit device 105b, first circuit board 15 includes a third coil pattern 22 surrounding at least a part of core 10 (e.g., second leg 11b of core 10). Third coil pattern 22 is spaced away from first coil pattern 20 in the thickness direction of first substrate 30. Third coil pattern 22 is provided on first main surface 30a, on second main surface 30b, or in first substrate 30. First circuit board 15 is, for example, a double-sided wiring board with first coil pattern 20 provided on second main surface 30b and third coil pattern 22 provided on first main surface 30a. In a plan view of second main surface 30b, third coil pattern 22 may have the same shape as that of first coil pattern 20 or may have a shape different from that of first coil pattern 20.

Third coil pattern 22 is electrically connected to first coil pattern 20 with a first via electrode 27 therebetween. First via electrode 27 extends in the thickness direction of first substrate 30. First via electrode 27 may extend from first main surface 30a to second main surface 30b. First via electrode 27 may be formed by filling holes extending in the thickness direction of first substrate 30 with a conductive material (e.g., metallic material) or may be formed by depositing a conductive film (e.g., metallic film) on surfaces of the holes extending in the thickness direction of first substrate 30.

In circuit device 105b, second circuit board 16 includes a fourth coil pattern 23 surrounding at least a part of core 10. Fourth coil pattern 23 is spaced away from second coil pattern 21 in the thickness direction of second substrate 31. Fourth coil pattern 23 is provided on third main surface 31a, on fourth main surface 31b, or in second substrate 31. Second circuit board 16 is, for example, a double-sided wiring board with second coil pattern 21 provided on fourth main surface 31b and fourth coil pattern 23 provided on third main surface 31a. In a plan view of fourth main surface 31b, fourth coil pattern 23 may have the same shape as that of second coil pattern 21 or may have a shape different from that of second coil pattern 21.

Fourth coil pattern 23 is electrically connected to second coil pattern 21 with a second via electrode 28 therebetween. Second via electrode 28 extends in the thickness direction of second substrate 31. Second via electrode 28 may extend from third main surface 31a to fourth main surface 31b. Second via electrode 28 may be formed by filling holes extending in the thickness direction of second substrate 31 with a conductive material (e.g., metallic material) or may be formed by depositing a conductive film (e.g., metallic film) on surfaces of the holes extending in the thickness direction of second substrate 31.

First heat transfer member 50 having electrical insulating properties may be in surface contact with third coil pattern 22 and heat dissipation member 60. Second heat transfer member 51 having electrical insulating properties may be in surface contact with first coil pattern 20 and fourth coil pattern 23.

It suffices that circuit device 105b includes at least one of third coil pattern 22 and fourth coil pattern 23. First circuit board 15 may include three or more layers of coil patterns. Second circuit board 16 may include three or more layers of coil patterns. For example, first circuit board 15 may further include a coil pattern (not shown) inside first substrate 30. Second circuit board 16 may further include a coil pattern (not shown) inside second substrate 31.

Circuit device 105b of the present embodiment achieves the following effects similar to those of circuit device 105 of Embodiment 1.

In circuit device 105b of the present embodiment, first circuit board 15 includes third coil pattern 22 surrounding at least a part of core 10. Third coil pattern 22 is spaced away from first coil pattern 20 in the thickness direction of first substrate 30 and is electrically connected to first coil pattern 20 with first via electrode 27 therebetween.

As a current is flowed through first coil pattern 20, second coil pattern 21, and third coil pattern 22 to operate circuit device 105b, first coil pattern 20, second coil pattern 21, and third coil pattern 22 generate heat. The heat generated in first coil pattern 20 and third coil pattern 22 is transferred through first heat transfer member 50 to heat dissipation member 60 with a relatively low thermal resistance. The heat generated in second coil pattern 21 is transferred through second heat transfer member 51, first circuit board 15, and first heat transfer member 50 to heat dissipation member 60 with a relatively low thermal resistance. Since the heat generated in first coil pattern 20 is transferred to third coil pattern 22, overheating of first coil pattern 20 can be prevented or reduced. A temperature rise and a power loss of circuit device 105b during operation of circuit device 105b can thus be prevented or reduced.

In circuit device 105b of the present embodiment, second circuit board 16 includes fourth coil pattern 23 surrounding at least a part of core 10. Fourth coil pattern 23 is spaced away from second coil pattern 21 in the thickness direction of second substrate 31 and is electrically connected to second coil pattern 21 through second via electrode 28.

As a current is flowed through first coil pattern 20, second coil pattern 21, and fourth coil pattern 23 to operate circuit device 105b, first coil pattern 20, second coil pattern 21, and fourth coil pattern 23 generate heat. The heat generated in first coil pattern 20 is transferred through first heat transfer member 50 to heat dissipation member 60 with a relatively low thermal resistance. The heat generated in second coil pattern 21 and fourth coil pattern 23 is transferred through second heat transfer member 51, first circuit board 15, and first heat transfer member 50 to heat dissipation member 60 with a relatively low thermal resistance. Since the heat generated in second coil pattern 21 is transferred to fourth coil pattern 23, overheating of second coil pattern 21 can be prevented or reduced. A temperature rise and a power loss in circuit device 105b during operation of circuit device 105b can thus be prevented or reduced.

### Embodiment 3

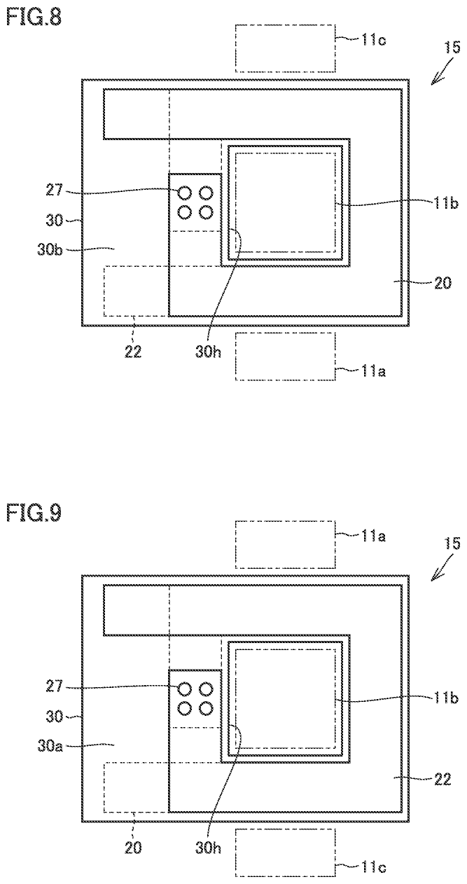

A circuit device according to Embodiment 3 will be described with reference to FIGS. 8 to 11. The circuit device of the present embodiment is similar in configuration to circuit device 105b of Embodiment 2 and is different mainly in the following respects.

In the present embodiment, a first amount of heat generation in first circuit board 15 is larger than a second amount of heat generation in second circuit board 16. Herein, the first amount of heat generation in first circuit board 15 means an amount of heat generated in all the coil patterns (e.g., first coil pattern 20 and third coil pattern 22) formed in first circuit board 15. The second amount of heat generation in second circuit board 16 means an amount of heat generated in all the coil patterns (e.g., second coil pattern 21 and fourth coil pattern 23) formed in second circuit board 16. First coil pattern 20 to fourth coil pattern 23 are designed such that the first amount of heat generation in first circuit board 15 is larger than the second amount of heat generation in second circuit board 16. Compared with second circuit board 16, first circuit board 15 has a large amount of heat generation and is disposed close to heat dissipation member 60. A temperature rise of the circuit device of the present embodiment can thus be reduced.

The turn ratio between primary-side coil conductor 120 and secondary-side coil conductor 121 is determined depending on the specifications of the circuit device and the power conversion apparatus. A ratio between a voltage applied to primary-side coil conductor 120 and a voltage applied to secondary-side coil conductor 121 and a ratio between a current flowing through primary-side coil conductor 120 and a current flowing through secondary-side coil conductor 121 are determined in accordance with the turn ratio. The shape and the number of layers of coil patterns formed in each of first circuit board 15 and second circuit board 16 are determined in accordance with the turn ratio. In other words, the lengths of the coil patterns formed in first circuit board 15 and second circuit board 16 are determined in accordance with the turn ratio. At least one of a width, a thickness, or an electrical resistivity of a coil pattern formed in each of first circuit board 15 and second circuit board 16 is determined such that the first amount of heat generation in first circuit board 15 is larger than the second amount of heat generation in second circuit board 16.

A case where primary-side coil conductor 120 is formed in first circuit board 15 and secondary-side coil conductor 121 is formed in second circuit board 16 will be considered below. As shown in FIGS. 8 and 9, each of first coil pattern 20 and third coil pattern 22 is wound seven-eighths of a turn around second leg 11b of core 10. First coil pattern 20 and third coil pattern 22 are electrically connected in series with each other by first via electrode 27. First coil pattern 20 and third coil pattern 22 are wound two turns around second leg 11b of core 10 as a whole. In other words, primary-side coil conductor 120 is a series conductor of two turns.

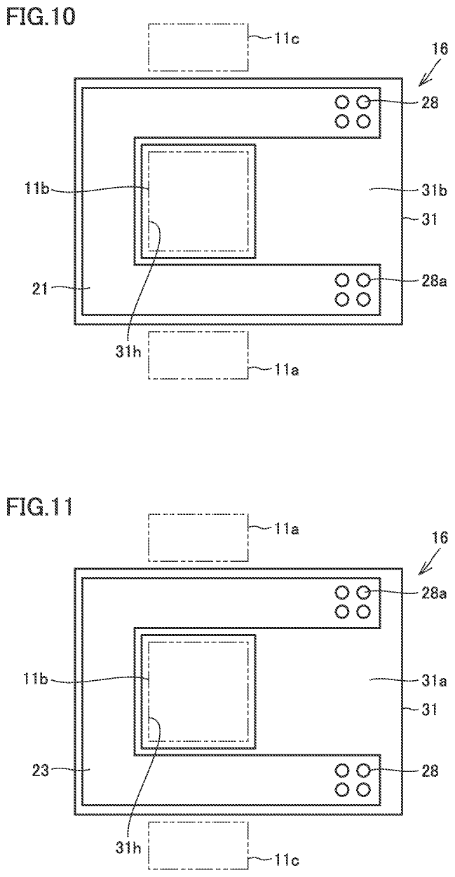

As shown in FIGS. 10 and 11, each of second coil pattern 21 and fourth coil pattern 23 is wound one turn around second leg 11b of core 10. Second coil pattern 21 and fourth coil pattern 23 are electrically connected in parallel with each other by second via electrode 28 and a third via electrode 28a. In other words, secondary-side coil conductor 121 is two-parallel-connected conductor of one turn. The turn ratio between primary-side coil conductor 120 and secondary-side coil conductor 121 is 2:1.

An amount of heat generation W₁ (W) of primary-side coil conductor 120 is given by Equation (1)

W₁=I₁×V₁=I₁²×R₁ (1)

where V₁ denotes a first voltage (V) applied to primary-side coil conductor 120, I₁ denotes a first current (A) flowing through primary-side coil conductor 120, and R₁ denotes a first resistance value (Ω) of primary-side coil conductor 120.

An amount of heat generation W₂ (W) of secondary-side coil conductor 121 is given by Equation (2)

W₂=I₂×V₂=I₂²×R₂ (2)

where V₂ denotes a second voltage (V) applied to secondary-side coil conductor 121, I₂ denotes a second current (A) flowing through secondary-side coil conductor 121, and R₂ denotes a second resistance value (Ω) of secondary-side coil conductor 121.

First coil pattern 20 has a width b₁ (m), a length L₁ (m), a thickness t₁ (m), and an electrical resistivity ρ₁ (Ω·m). Second coil pattern 21 has a width b₂ (m), a length L₂ (m), a thickness t₂ (m), and an electrical resistivity ρ₂ (Ω·m). Third coil pattern 22 has a width b₃ (m), a length L₃ (m), a thickness t₃ (m), and an electrical resistivity ρ₃ (Ω·m). Fourth coil pattern 23 has a width b₄ (m), a length L₄ (m), a thickness t₄ (m), and an electrical resistivity ρ₄ (Ω·m). First resistance value R₁ of primary-side coil conductor 120 is given by Equation (3). Second resistance value R₂ of secondary-side coil conductor 121 is given by Equation (4).

$$\begin{matrix}[ Math 1 ] & \\ {R}_{1} = ( {ρ}_{1} \frac{{L}_{1}}{{b}_{1} {t}_{1}} ) + ( {ρ}_{3} \frac{{L}_{3}}{{b}_{3} {t}_{3}} ) & ( 3 ) \\ [ Math 2 ] & \\ {R}_{2}^{- 1} = {( {ρ}_{2} \frac{{L}_{2}}{{b}_{2} {t}_{2}} )}^{- 1} + {( {ρ}_{4} \frac{{L}_{4}}{{b}_{4} {t}_{4}} )}^{- 1} & ( 4 )\end{matrix}$$

Since the turn ratio between primary-side coil conductor 120 and secondary-side coil conductor 121 is 2:1, V₁:V₂=2:1 and I₁:I₂=1:2. Here, when ρ₁ to ρ₄ are equal to each other, b₁ to b₄ are equal to each other, L₁ to L₄ are equal to teach other, t₁ and t₃ are equal to each other, and t₂ and t₄ are equal to each other, a ratio of amount of heat generation W₁ of primary-side coil conductor 120 to amount of heat generation W₂ of secondary-side coil conductor 121 is given by Equation (5). Thickness t₁ of first coil pattern 20 and thickness t₂ of second coil pattern 21 are determined such that W₁/W₂ is greater than one.

W₁/W₂=t₂/2t₁ (5)

Also for a case where t₁ and t₃ are different from reach other and t₂ and t₄ are different from each other, thickness t₁ of first coil pattern 20, thickness t₂ of second coil pattern 21, thickness t₃ of third coil pattern 22, and thickness t₄ of fourth coil pattern 23 are determined such that W₁/W₂ is greater than one. When amount of heat generation W₂ of secondary-side coil conductor 121 is larger than amount of heat generation W₁ of primary-side coil conductor 120, secondary-side coil conductor 121 is formed in first circuit board 15, and primary-side coil conductor 120 is formed in second circuit board 16.

First circuit board 15 may include three or more layers of coil patterns. Second circuit board 16 may include three or more layers of coil patterns. For example, first circuit board 15 may further include a coil pattern (not shown) inside first substrate 30. Second circuit board 16 may further include a coil pattern (not shown) inside second substrate 31.

### Embodiment 4

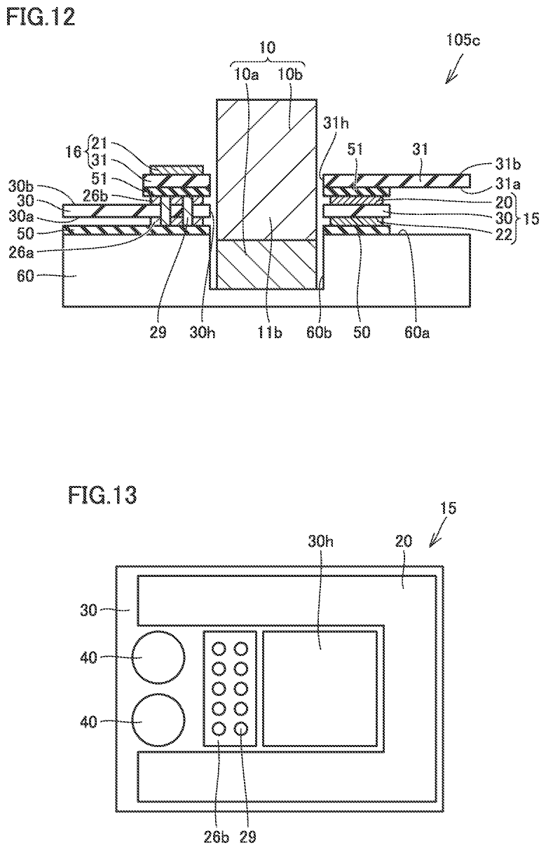

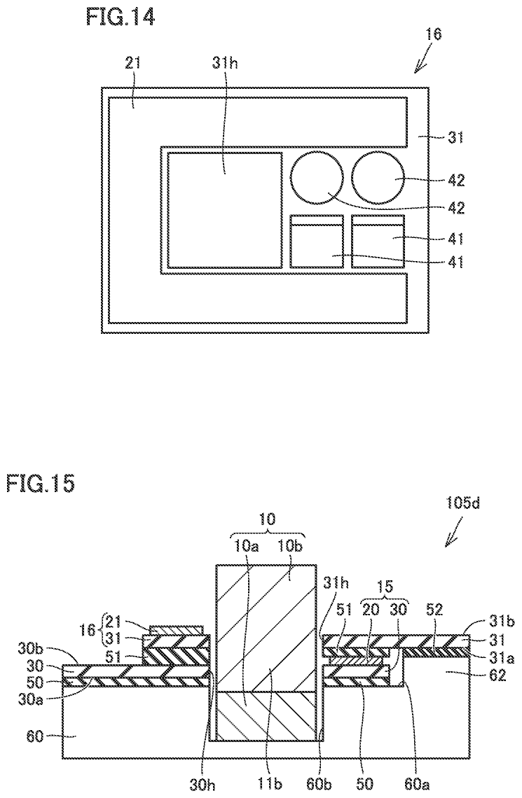

Circuit device 105c according to Embodiment 4 will be described with reference to FIGS. 12 to 14. Circuit device 105c of the present embodiment is similar in configuration to circuit device 105 of Embodiment 1 and is different mainly in the following respects.

In circuit device 105c, first circuit board 15 includes a heat transfer via 29 passing through first substrate 30. Heat transfer via 29 is in contact with first heat transfer member 50 and second heat transfer member 51. Heat transfer via 29 extends in the thickness direction of first substrate 30 and extends from third main surface 31a to fourth main surface 31b. Heat transfer via 29 may be formed by filling holes extending from third main surface 31a to fourth main surface 31b with a thermally conductive material (e.g., metallic material) or may be formed by depositing a thermally conductive film (e.g., metallic film) on surfaces of the holes extending from third main surface 31a to fourth main surface 31b. Heat transfer via 29 has a thermal conductivity higher than that of first substrate 30.

First circuit board 15 may further include third coil pattern 22 provided on first main surface 30a. First circuit board 15 may further include a first conductive pattern 26a provided on first main surface 30a. First conductive pattern 26a is formed of the same material as that of third coil pattern 22. First conductive pattern 26a may be electrically insulated from the coil patterns (e.g., first coil pattern 20, second coil pattern 21, and third coil pattern 22).

First circuit board 15 may further include a second conductive pattern 26b provided on second main surface 30b. Second conductive pattern 26b is formed of the same material as that of first coil pattern 20. Second conductive pattern 26b may be electrically insulated from the coil patterns (e.g., first coil pattern 20, second coil pattern 21, and third coil pattern 22). Heat transfer via 29 may be in contact with first conductive pattern 26a and second conductive pattern 26b. Heat transfer via 29 may function as a third via electrode electrically connecting second conductive pattern 26b to first conductive pattern 26a.

Circuit device 105c of the present embodiment achieves the following effects similar to those of circuit device 105 of Embodiment 1.

In circuit device 105c of the present embodiment, first circuit board 15 includes heat transfer via 29 passing through first substrate 30. Heat transfer via 29 is in contact with first heat transfer member 50 and second heat transfer member 51. As a current is flowed through first coil pattern 20, second coil pattern 21, and third coil pattern 22 to operate circuit device 105c, first coil pattern 20, second coil pattern 21, and third coil pattern 22 generate heat. The heat generated in first coil pattern 20 and third coil pattern 22 is transferred through first heat transfer member 50 to heat dissipation member 60 with a relatively low thermal resistance. The heat generated in second coil pattern 21 is transferred through second heat transfer member 51, heat transfer via 29, and first heat transfer member 50 to heat dissipation member 60 with a lower thermal resistance. A temperature rise and a power loss in circuit device 105c during operation of circuit device 105c can thus be prevented or reduced.

### Embodiment 5

Circuit device 105d according to Embodiment 5 will be described with reference to FIG. 15. Circuit device 105d of the present embodiment is similar in configuration to circuit device 105 of Embodiment 1 and is different mainly in the following respects.

Heat dissipation member 60 includes a first projection 62 projecting from surface 60a toward second circuit board 16. First projection 62 may be a member separate from a portion of heat dissipation member 60 other than first projection 62. First projection 62 may be made of a material different from that of heat dissipation member 60.

Circuit device 105d further includes a third heat transfer member 52. Third heat transfer member 52 is disposed between second circuit board 16 and first projection 62 and is in surface contact with second circuit board 16 and first projection 62. Second circuit board 16, third heat transfer member 52, and first projection 62 are stacked on each other. Third heat transfer member 52 thermally connects second circuit board 16 to first projection 62. Third heat transfer member 52 is a third heat transfer sheet. Third heat transfer member 52 may have electrical insulating properties.

Third heat transfer member 52 may be formed of a rubber material such as silicone or urethane, a resin material such as acrylonitrile butadiene styrene (ABS), polybutylene terephthalate (PBT), polyphenylene sulfide (PPS), epoxy, phenol, or polyimide, or a ceramic material such as aluminum oxide or aluminum nitride. Third heat transfer member 52 may be formed of a silicone gel, a silicone grease, or a silicone adhesive.

Third heat transfer member 52 has a thermal conductivity of not less than 0.1 W/(m·K). First heat transfer member 50 may have a thermal conductivity of not less than 1.0 W/(m·K) or may have a thermal conductivity of not less than 10.0 W/(m·K). Third heat transfer member 52 may have elasticity. Third heat transfer member 52 may be crushed by pressing second circuit board 16 toward heat dissipation member 60.

Circuit device 105d of the present embodiment achieves the following effects in addition to the effects of circuit device 105 of Embodiment 1.

Circuit device 105d of the present embodiment further includes third heat transfer member 52. Heat dissipation member 60 includes surface 60a facing first circuit board 15 and first projection 62 projecting from surface 60a toward second circuit board 16. Third heat transfer member 52 is disposed between second circuit board 16 and first projection 62 and is in surface contact with second circuit board 16 and first projection 62.

The heat generated in second coil pattern 21 in flowing a current through first coil pattern 20 and second coil pattern 21 to operate circuit device 105d is transferred through a first heat dissipation path including second heat transfer member 51, first circuit board 15, and first heat transfer member 50 and a second heat dissipation path including third heat transfer member 52 to heat dissipation member 60 with a lower thermal resistance. A temperature rise and a power loss of circuit device 105d during operation of circuit device 105d can thus be prevented or reduced.

Second circuit board 16 is supported by first projection 62 with third heat transfer member 52 therebetween. Deformation of and mechanical damage to second circuit board 16 due to vibrations or an impact applied to circuit device 105d can thus be prevented or reduced.

### Embodiment 6

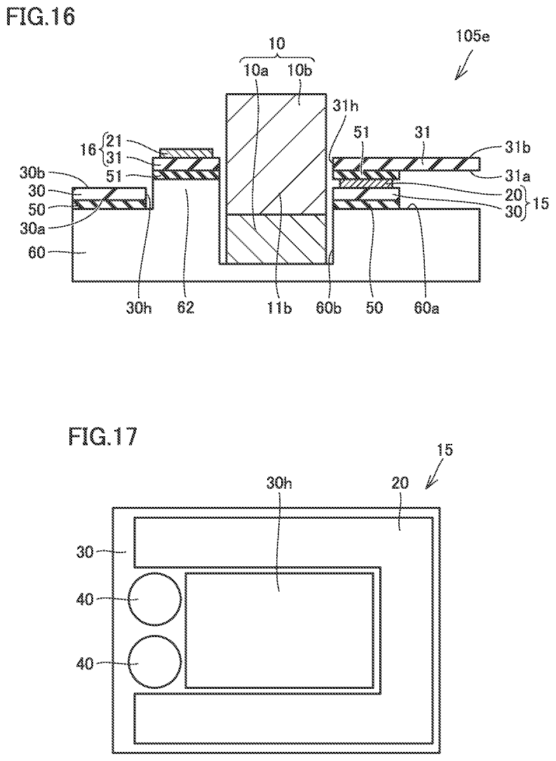

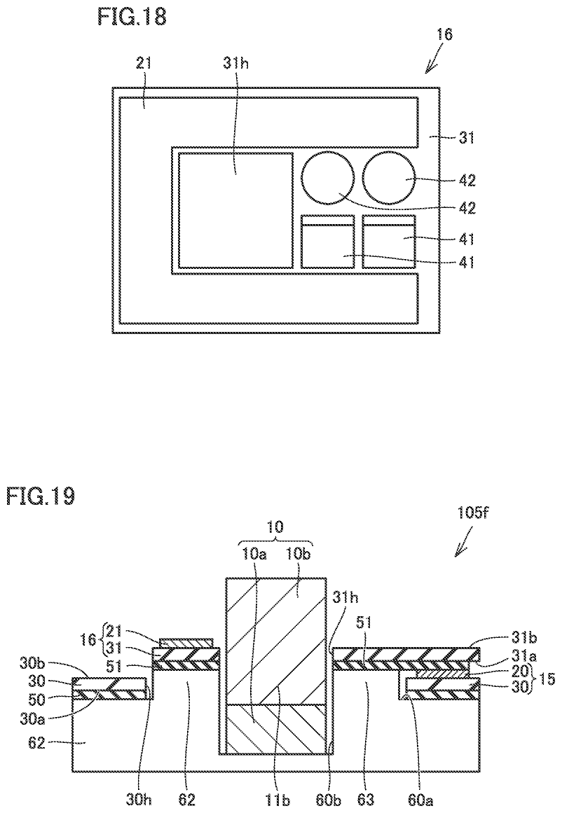

Circuit device 105e according to Embodiment 6 will be described with reference to FIGS. 16 to 18. Circuit device 105e of the present embodiment is similar in configuration to circuit device 105 of Embodiment 1 and is different mainly in the following respects.

Heat dissipation member 60 includes first projection 62 projecting from surface 60a toward second circuit board 16. First projection 62 may be a member separate from a portion of heat dissipation member 60 other than first projection 62. First projection 62 may be made of a material different from that of the portion of heat dissipation member 60.

A part of core 10 (e.g., second leg 11b of core 10) and first projection 62 are inserted into first through hole 30h. A part of core 10 (e.g., second leg 11b of core 10) is inserted into second through hole 31h, but first projection 62 is not inserted into second through hole 31h. First projection 62 passes through first circuit board 15 (first substrate 30) but does not pass through second circuit board 16 (first substrate 30).

Second heat transfer member 51 is disposed between second circuit board 16 and first projection 62 and is in surface contact with second circuit board 16 and first projection 62. Second circuit board 16, second heat transfer member 51, and first projection 62 are stacked on each other. Second heat transfer member 51 thermally connects second circuit board 16 to first projection 62. In a plan view of surface 60a of heat dissipation member 60, first projection 62 may overlap a part of second coil pattern 21.

Circuit device 105e of the present embodiment achieves the following effects in addition to the effects of circuit device 105 of Embodiment 1.

In circuit device 105e of the present embodiment, heat dissipation member 60 includes surface 60a facing first circuit board 15 and first projection 62 projecting from surface 60a toward second circuit board 16. Second heat transfer member 51 is disposed between second circuit board 16 and first projection 62 and is in surface contact with second circuit board 16 and first projection 62. First substrate 30 is provided with first through hole 30h. A part of core 10 (second leg 11b of core 10) and first projection 62 are inserted into first through hole 30h.

The heat generated in second coil pattern 21 in flowing a current through first coil pattern 20 and second coil pattern 21 to operate circuit device 105e is transferred through the first heat dissipation path including second heat transfer member 51, first circuit board 15, and first heat transfer member 50 and the second heat dissipation path including second heat transfer member 51 and first projection 62 to heat dissipation member 60 with a lower thermal resistance. A temperature rise and a power loss of circuit device 105e during operation of circuit device 105e can thus be prevented or reduced.

Second circuit board 16 is supported by first projection 62 with second heat transfer member 51 therebetween. Deformation of and mechanical damage to second circuit board 16 due to vibrations or an impact applied to circuit device 105e can thus be prevented or reduced.

A part of core 10 (second leg 11b of core 10) and first projection 62 are inserted into first through hole 30h. First circuit board 15 and core 10 can thus be aligned with respect to heat dissipation member 60. First circuit board 15 and core 10 can be prevented from being displaced with respect to heat dissipation member 60 in the direction along surface 60a of heat dissipation member 60 due to vibrations or an impact applied to circuit device 105e.

In circuit device 105e of the present embodiment, first projection 62 may overlap a part of second coil pattern 21 in a plan view of surface 60a of heat dissipation member 60. The heat generated in second coil pattern 21 in flowing a current through first coil pattern 20 and second coil pattern 21 to operate circuit device 105e is thus transferred through the second heat dissipation path including second heat transfer member 51 and first projection 62 to heat dissipation member 60 with a lower thermal resistance. A temperature rise and a power loss of circuit device 105e during operation of circuit device 105e can be prevented or reduced.

### Embodiment 7

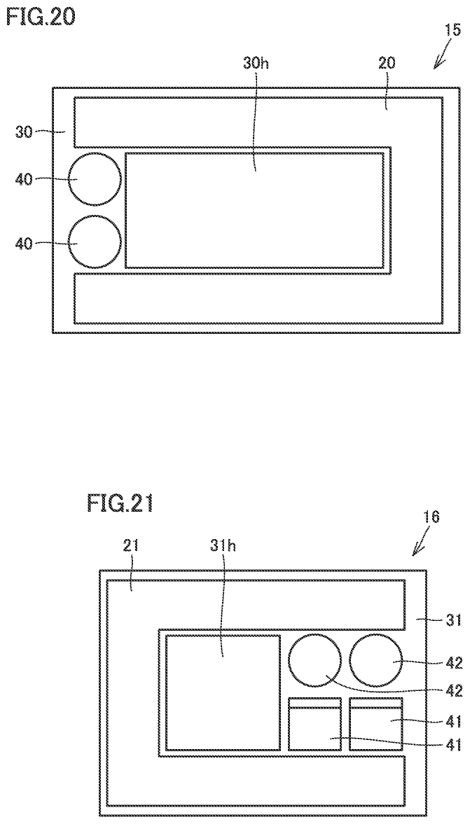

Circuit device 105f according to Embodiment 7 will be described with reference to FIGS. 19 to 21. Circuit device 105f of the present embodiment is similar in configuration to circuit device 105e of Embodiment 6 and is different mainly in the following respects.

Heat dissipation member 60 further includes a second projection 63 projecting from surface 60a toward second circuit board 16. Second projection 63 may be a member separate from a part of heat dissipation member 60 other than first projection 62 and second projection 63. Second projection 63 may be made of a material different from that of the portion of heat dissipation member 60.

A part of core 10 (e.g., second leg 11b of core 10) and second projection 63 are inserted into first through hole 30h. A part of core 10 (e.g., second leg 11b of core 10) is inserted into second through hole 31h, but second projection 63 is not inserted into second through hole 31h. Second projection 63 passes through first circuit board 15 (first substrate 30) but does not pass through second circuit board 16 (second substrate 31). A part of core 10 (e.g., second leg 11b of core 10) is disposed between first projection 62 and second projection 63.

Second heat transfer member 51 is disposed between second circuit board 16 and second projection 63 and is in surface contact with second circuit board 16 and second projection 63. Second circuit board 16, second heat transfer member 51, and second projection 63 are stacked on each other. Second heat transfer member 51 thermally connects second circuit board 16 to second projection 63.

Circuit device 105f of the present embodiment achieves the following effects in addition to the effects of circuit device 105e of Embodiment 6.

In circuit device 105f of the present embodiment, heat dissipation member 60 further includes second projection 63 projecting from surface 60a toward second circuit board 16. Second heat transfer member 51 is disposed between second circuit board 16 and second projection 63 and is in surface contact with second circuit board 16 and second projection 63. First substrate 30 is provided with first through hole 30h. A part of core 10 (second leg 11b of core 10), first projection 62, and second projection 63 are inserted into first through hole 30h.

The heat generated in second coil pattern 21 in flowing a current through first coil pattern 20 and second coil pattern 21 to operate circuit device 105f is transferred through the first heat dissipation path including second heat transfer member 51, first circuit board 15, and first heat transfer member 50, the second heat dissipation path including second heat transfer member 51 and first projection 62, and a third heat dissipation path including second heat transfer member 51 and second projection 63 to heat dissipation member 60 with a lower thermal resistance. A temperature rise and a power loss of circuit device 105f during operation of circuit device 105f can thus be prevented or reduced.

Second circuit board 16 is supported by first projection 62 and second projection 63 with second heat transfer member 51 therebetween. Deformation of and mechanical damage to second circuit board 16 due to vibrations or an impact applied to circuit device 105f can thus be prevented or reduced.

A part of core 10 (second leg 11b of core 10), first projection 62, and second projection 63 are inserted into first through hole 30h. First circuit board 15 and core 10 can thus be aligned with respect to heat dissipation member 60. First circuit board 15 and core 10 can be prevented from being displaced with respect to heat dissipation member 60 in the direction along surface 60a of heat dissipation member 60 due to vibrations or an impact applied to circuit device 105f.

### Embodiment 8

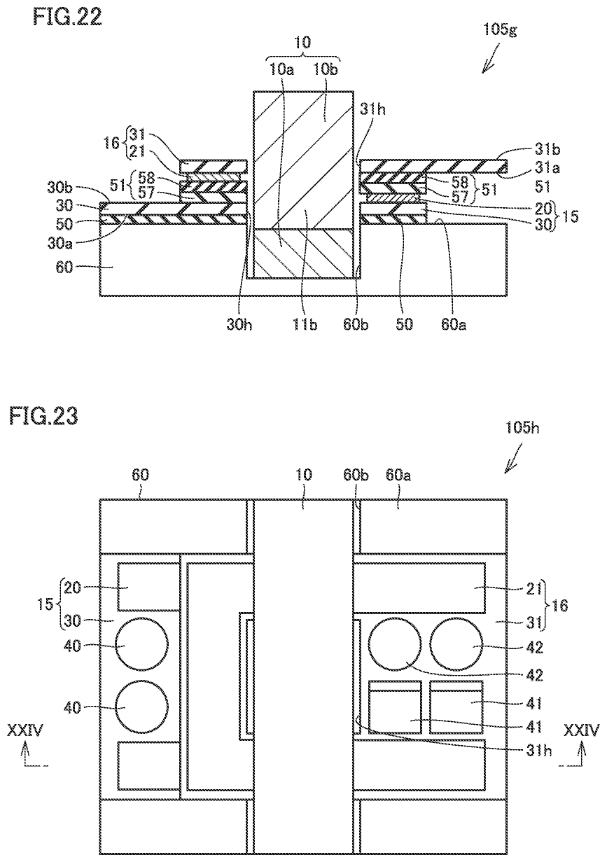

Circuit device 105g according to Embodiment 8 will be described with reference to FIG. 22. Circuit device 105g of the present embodiment is similar in configuration to circuit device 105 of Embodiment 1 and is different mainly in the following respects.

In circuit device 105g, second heat transfer member 51 is composed of a plurality of heat-transfer partial layers (e.g., a first heat-transfer partial layer 57 and a second heat-transfer partial layer 58). The plurality of heat-transfer partial layers are stacked on each other. For example, second heat transfer member 51 is formed by stacking first heat-transfer partial layer 57 and second heat-transfer partial layer 58. First heat-transfer partial layer 57 is in surface contact with first circuit board 15. Second heat-transfer partial layer 58 is in surface contact with second circuit board 16. Each of the plurality of heat-transfer partial layers (e.g., first heat-transfer partial layer 57 and second heat-transfer partial layer 58) has electrical insulating properties. The plurality of heat-transfer partial layers may have the same thickness or a different thickness. The plurality of heat-transfer partial layers may be made of the same material or may be made of a different material.

Second coil pattern 21 is provided on third main surface 31a. Second heat transfer member 51 having electrical insulating properties is in surface contact with first coil pattern 20 and second coil pattern 21.

Circuit device 105g of the present embodiment achieves the following effects in addition to the effects of circuit device 105 of Embodiment 1. In circuit device 105g of the present embodiment, second heat transfer member 51 is composed of a plurality of heat-transfer partial layers. The plurality of heat-transfer partial layers are stacked on each other. Each of the plurality of heat-transfer partial layers has electrical insulating properties. Accordingly, even if a partial layer of a plurality of heat-transfer partial layers includes a void and a dielectric breakdown occurs in the partial layer of the plurality of heat-transfer partial layers during operation of circuit device 105g, the other layers of the plurality of heat-transfer partial layers can maintain electrical insulation between first coil pattern 20 and second coil pattern 21. The occurrence of an electrical discharge (e.g., partial discharge or corona discharge) between first coil pattern 20 and second coil pattern 21 due to the void can be prevented or reduced during operation of circuit device 105g. Second coil pattern 21 can be electrically insulated from first coil pattern 20 more reliably.

### Embodiment 9

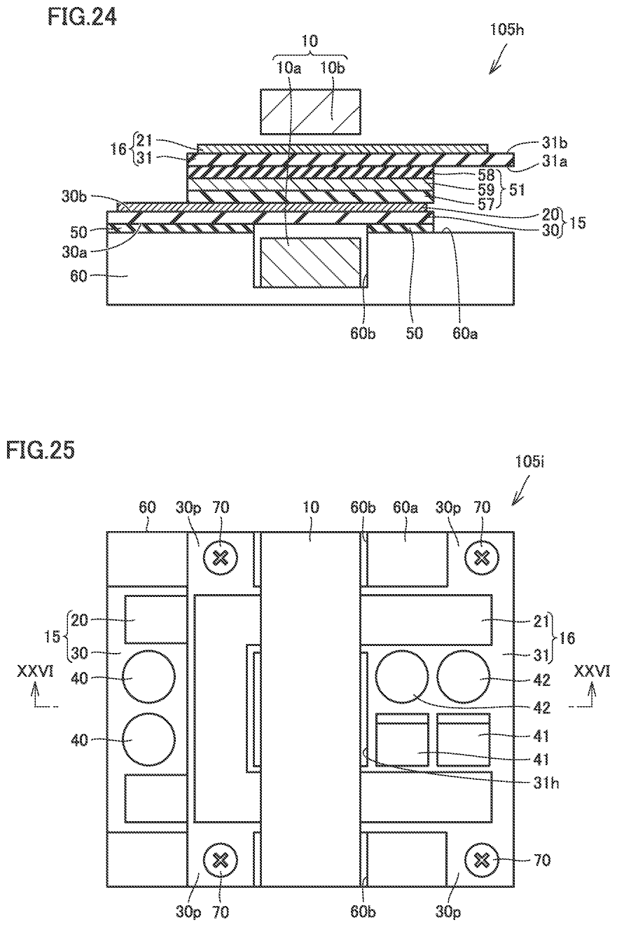

Circuit device 105h according to Embodiment 9 will be described with reference to FIGS. 23 and 24. Although circuit device 105h of the present embodiment is similar in configuration to circuit device 105g of Embodiment 8 and achieves effects similar to those of circuit device 105g of Embodiment 8, circuit device 105h is different from mainly in the following respects.

In circuit device 105h of the present embodiment, second heat transfer member 51 includes first heat-transfer partial layer 57, second heat-transfer partial layer 58, and a third heat-transfer partial layer 59. First heat-transfer partial layer 57, second heat-transfer partial layer 58, and third heat-transfer partial layer 59 are stacked on each other. First heat-transfer partial layer 57 has electrical insulating properties and is in surface contact with first circuit board 15. Second heat-transfer partial layer 58 has electrical insulating properties and is in surface contact with second circuit board 16. Third heat-transfer partial layer 59 is disposed between first heat-transfer partial layer 57 and second heat-transfer partial layer 58. Third heat-transfer partial layer 59 has a thermal conductivity higher than that of each of first heat-transfer partial layer 57 and second heat-transfer partial layer 58. Third heat-transfer partial layer 59 has, for example, a thermal conductivity of not less than 10.0 W/(m·K).

Third heat-transfer partial layer 59 may have conductivity or may have electrical insulating properties. Third heat-transfer partial layer 59 is formed of, for example, a metallic material such as copper (Cu), silver (Ag), gold (Au), tin (Sn), iron (Fe), copper (Cu) alloy, nickel (Ni) alloy, gold (Au) alloy, silver (Ag) alloy, tin (Sn) alloy, or iron (Fe) alloy. Third heat-transfer partial layer 59 may be formed of a non-metallic material such as graphite or ceramic. Third heat-transfer partial layer 59 is electrically insulated from first coil pattern 20 by first heat-transfer partial layer 57. Third heat-transfer partial layer 59 is electrically insulated from second coil pattern 21 by second heat-transfer partial layer 58. Third heat-transfer partial layer 59 is not magnetically coupled to first coil pattern 20 and second coil pattern 21. Third heat-transfer partial layer 59 thus does not generate heat during operation of circuit device 105h.

The effects of circuit device 105h according to the present embodiment will be described. Circuit device 105h of the present embodiment achieves the following effects in addition to the effects of circuit device 105g of Embodiment 8.

In circuit device 105h of the present embodiment, second heat transfer member 51 includes first heat-transfer partial layer 57, second heat-transfer partial layer 58, and third heat-transfer partial layer 59. First heat-transfer partial layer 57, second heat-transfer partial layer 58, and third heat-transfer partial layer 59 are stacked on each other. First heat-transfer partial layer 57 has electrical insulating properties and is in surface contact with first circuit board 15. Second heat-transfer partial layer 58 has electrical insulating properties and is in surface contact with second circuit board 16. Third heat-transfer partial layer 59 is disposed between first heat-transfer partial layer 57 and second heat-transfer partial layer 58 and has a thermal conductivity higher than that of each of first heat-transfer partial layer 57 and second heat-transfer partial layer 58. Third heat-transfer partial layer 59 thus diffuses the heat generated in first coil pattern 20 and second coil pattern 21 in the direction in which third heat-transfer partial layer 59 extends (the direction along surface 60a of heat dissipation member 60). Local overheating of circuit device 105h can be prevented during operation of circuit device 105h. A temperature rise and a power loss of circuit device 105h during operation of circuit device 105h can be prevented or reduced.

### Embodiment 10

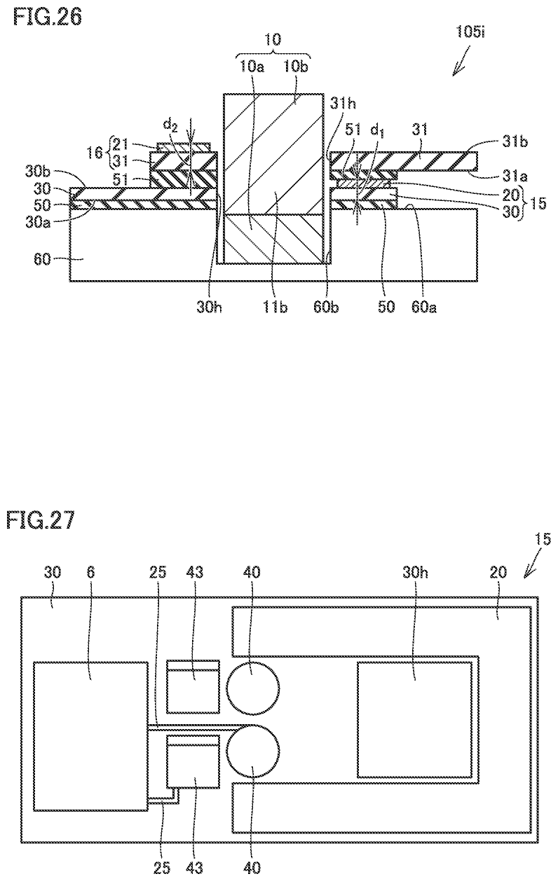

Circuit device 105i according to Embodiment 10 will be described with reference to FIGS. 25 and 26. Circuit device 105i of the present embodiment is similar in configuration to circuit device 105 of Embodiment 1 and is different mainly in the following respects.

In circuit device 105i, a second thickness d₂ of second circuit board 16 is larger than a first thickness d₁ of first circuit board 15. When first coil pattern 20 is formed on first main surface 30a or on second main surface 30b in first circuit board 15, first thickness d₁ of first circuit board 15 is defined as the sum of the thickness of first substrate 30 and the thickness of first coil pattern 20. When first coil pattern 20 is formed inside first substrate 30 in first circuit board 15, first thickness d₁ of first circuit board 15 is defined as the thickness of first substrate 30.

When second coil pattern 21 is formed on third main surface 31a or on fourth main surface 31b in second circuit board 16, second thickness d₂ of second circuit board 16 is defined as the sum of the thickness of second substrate 31 and the thickness of second coil pattern 21. When second coil pattern 21 is formed inside second substrate 31 in second circuit board 16, second thickness d₂ of second circuit board 16 is defined as the thickness of second substrate 31. First circuit board 15 and second circuit board 16 are fixed to heat dissipation member 60 with fixing member 70 such as a screw, a mechanical screw, or a rivet.

Circuit device 105i of the present embodiment achieves the following effects in addition to the effects of circuit device 105 of Embodiment 1. In circuit device 105i of the embodiment, second thickness d₂ of second circuit board 16 is larger than first thickness d₁ of first circuit board 15. Second circuit board 16 thus has rigidity higher than that of first circuit board 15. Circuit device 105i can be prevented from being mechanically damaged due to vibrations or an impact applied to circuit device 105i.

### Embodiment 11

A circuit device and a power conversion apparatus according to Embodiment 11 will be described with reference to FIG. 27. The circuit device and the power conversion apparatus of the present embodiment have configurations similar to those of circuit device 105 and power conversion apparatus 1 of Embodiment 1 and are different mainly in the following respects.

In the circuit device and the power conversion apparatus of the present embodiment, control circuit 6 that controls first electronic components 40, 43 forming inverter circuit 2 (see FIG. 1) is disposed on at least one of first circuit board 15 and second circuit board 16. For example, control circuit 6 is disposed on first circuit board 15 (particularly, second main surface 30b).

At least one of first circuit board 15 and second circuit board 16 includes a third conductive pattern 25. Third conductive pattern 25 electrically connects control circuit 6 to first electronic components 40, 43. For example, first circuit board 15 includes third conductive pattern 25 provided on first substrate 30 (particularly, on second main surface 30b). A current flowing through third conductive pattern 25 is smaller than a current flowing through first coil pattern 20 and second coil pattern 21. The thickness of third conductive pattern 25 may thus be smaller than the thickness of first coil pattern 20. The thickness of third conductive pattern 25 may be smaller than the thickness of second coil pattern 21.

The circuit device and the power conversion apparatus of the present embodiment achieve the following effects in addition to the effects of Embodiment 1. In the circuit device and power conversion apparatus 1 of the present embodiment, control circuit 6 that controls first electronic components 40, 43 is mounted on at least one of first circuit board 15 and second circuit board 16. At least one of first circuit board 15 and second circuit board 16 includes third conductive pattern 25. Third conductive pattern 25 electrically connects control circuit 6 to first electronic components 40, 43.

Therefore, a cable and a connector for electrically connecting control circuit 6 with first electronic components 40, 43 can be omitted, leading to miniaturization of the circuit device and the power conversion apparatus. Further, the length of third conductive pattern 25 connecting control circuit 6 with first electronic components 40, 43 can be reduced, which may reduce the influence of electromagnetic noise on first electronic components 40, 43.

It should be understood that Embodiments 1 to 11 disclosed herein are illustrative and non-restrictive in every respect. At least two of Embodiments 1 to 11 disclosed herein may be combined unless there is inconsistency. For example, power conversion apparatus 1 includes any of circuit devices 105, 105b, 105c, 105d, 105e, 105f, 105g, 105h, 105i of Embodiments 1 to 11. The scope of the present invention is defined by the terms of the claims rather than the description above and is intended to include any modifications within the scope and meaning equivalent to the terms of the claims.

### REFERENCE SIGNS LIST

1 power conversion apparatus; 2 inverter circuit; 3 transformer circuit; 4 rectifier circuit; 5 smoothing circuit; 6 control circuit; 7a, 7b, 7c, 7d switching element; 8a, 8b, 8c, 8d diode; 9a, 9b capacitor; 10 core; 10a first core portion; 10b second core portion; 11a first leg; 11b second leg; 11c third leg; 15 first circuit board; 16 second circuit board; 20 first coil pattern; 21 second coil pattern; 22 third coil pattern; 23 fourth coil pattern; 25 third conductive pattern; 26a first conductive pattern; 26b second conductive pattern; 27 first via electrode; 28 second via electrode; 28a third via electrode; 29 heat transfer via; 30 first substrate; 30a first main surface; 30b second main surface; 30h first through hole; 31 second substrate; 31a third main surface; 31b fourth main surface; 31h second through hole; 40, 43 first electronic component; 41, 42 second electronic component; 50 first heat transfer member; 51 second heat transfer member; 52 third heat transfer member; 57 first heat-transfer partial layer; 58 second heat-transfer partial layer; 59 third heat-transfer partial layer; 60 heat dissipation member; 60a surface; 60b recess; 62 first projection; 63 second projection; 70 fixing member; 100, 102, 103 coil device; 101 transformer; 105, 105b, 105c, 105d, 105e, 105f, 105g, 105h, 105i circuit device; 110 input terminal; 111 output terminal; 120 primary-side coil conductor; 121 secondary-side coil conductor.

1. A circuit device comprising:
a core;
a first circuit board including a first substrate and a first coil pattern, the first coil pattern surrounding at least a part of the core;
a second circuit board including a second substrate and a second coil pattern, the second coil pattern surrounding at least a part of the core;
a heat dissipation member supporting the core, the first circuit board, and the second circuit board;
a first heat transfer member disposed between the first circuit board and the heat dissipation member and being in surface contact with the first circuit board and the heat dissipation member; and
a second heat transfer member disposed between the first circuit board and the second circuit board and being in surface contact with the first circuit board and the second circuit board.

2. The circuit device according to claim 1, wherein
the first circuit board includes a third coil pattern surrounding at least a part of the core, and
the third coil pattern is spaced away from the first coil pattern in a thickness direction of the first substrate and is electrically connected to the first coil pattern with a first via electrode therebetween.

3. The circuit device according to claim 1, wherein
the second circuit board includes a fourth coil pattern surrounding at least a part of the core, and
the fourth coil pattern is spaced away from the second coil pattern in a thickness direction of the second substrate and is electrically connected to the second coil pattern with a second via electrode therebetween.

4. The circuit device according to claim 1, wherein
the first circuit board includes a heat transfer via passing through the first substrate, and
the heat transfer via is in contact with the first heat transfer member and the second heat transfer member.

5. The circuit device according to claim 1, further comprising a third heat transfer member, wherein
the heat dissipation member includes
a surface facing the first circuit board, and
a projection projecting from the surface toward the second circuit board, and
the third heat transfer member is disposed between the second circuit board and the projection and is in surface contact with the second circuit board and the projection.

6. The circuit device according to claim 1, wherein
the heat dissipation member includes
a surface facing the first circuit board, and
a projection projecting from the surface toward the second circuit board,
the second heat transfer member is disposed between the second circuit board and the projection and is in surface contact with the second circuit board and the projection,
the first substrate is provided with a through hole, and
a part of the core and the projection are inserted into the through hole.

7. The circuit device according to claim 6, wherein the projection overlaps a part of the second coil pattern in a plan view of the surface.

8. The circuit device according to claim 1, wherein a first amount of heat generation in the first circuit board is larger than a second amount of heat generation in the second circuit board.

9. The circuit device according to claim 1, wherein
the second heat transfer member includes a plurality of heat-transfer partial layers,
the plurality of heat-transfer partial layers are stacked on each other, and
each of the plurality of heat-transfer partial layers has electrical insulating properties.

10. The circuit device according to claim 1, wherein
the second heat transfer member includes a first heat-transfer partial layer, a second heat-transfer partial layer, and a third heat-transfer partial layer,
the first heat-transfer partial layer, the second heat-transfer partial layer, and the third heat-transfer partial layer are stacked on each other,
the first heat-transfer partial layer has electrical insulating properties and is in surface contact with the first circuit board,
the second heat-transfer partial layer has electrical insulating properties and is in surface contact with the second circuit board, and
the third heat-transfer partial layer is disposed between the first heat-transfer partial layer and the second heat-transfer partial layer and has a thermal conductivity higher than that of each of the first heat-transfer partial layer and the second heat-transfer partial layer.

11. The circuit device according to claim 1, wherein the second circuit board has a second thickness larger than a first thickness of the first circuit board.

12. A power conversion apparatus comprising:
a circuit device according to claim 1; and
an inverter circuit that controls a current flowing through the first coil pattern.

13. The power conversion apparatus according to claim 12, wherein an electronic component forming the inverter circuit is mounted on at least one of the first circuit board and the second circuit board.

14. The power conversion apparatus according to claim 13, wherein
a control circuit that controls the electronic component is mounted on at least one of the first circuit board and the second circuit board, and
the at least one of the first circuit board and the second circuit board includes a conductive pattern, and the conductive pattern electrically connects the control circuit to the electronic component.
